(19) United States
(12) Patent Application Publication
(10) Pub. No.: US 2026/0352222 A1
(43) Pub. Date: Nov. 5, 2026

(54) SAMPLING AN ANALOG SIGNAL

(71) Applicant: Technion Research & Development Foundation Limited, Haifa (IL)

(72) Inventors: Alejandro Cohen, Haifa (IL); Aseel Omar, Haifa (IL); Saar Tarnopolsky, Haifa (IL); Vered Karp, Haifa (IL)

(73) Assignee: Technion Research & Development Foundation Limited, Haifa (IL)

(21) Appl. No.: 19/550,127

(22) Filed: Feb. 25, 2026

Related U.S. Application Data
(60) Provisional application No. 63/763,859, filed on Feb. 26, 2025.

(51) Int. Cl. H03M 1/12; H03M 1/34

(52) U.S. Cl. CPC H03M 1/1245; H03M 1/34

(57) ABSTRACT

A method for sampling an analog signal, the method includes preforming multiple sampling iterations to provide timing information that represents the analog signal at multiple points in time. Each sampling iteration includes adding an adaptive bias to the analog signal to provide a biased signal, wherein the adaptive bias is determined based on values of the analog signal during a set of previous sampling iterations; integrating the biased signal by an integrator to provide an integration result; comparing the integration result to a threshold; generating a timestamp when the integration result exceeds the threshold; generating a representation of a difference between the current timestamp to last generated timestamp.

### CROSS REFERENCE

This application claims priority from U.S. provisional patent Ser. No. 63/763,859 filing date Feb. 26, 2025, titled SAMPLING AN ANALOG SIGNAL which is incorporated herein by reference.

### BACKGROUND

Analog-to-digital converters (ADCs) are fundamental components in every digital system. Their main goal is to transform a continuous signal (for example—see FIG. 1—continuous sample 11-1) into a discrete signal, since in the real world it is impossible to perfectly represent a continuous signal in our computers. ADCs include a sampling stage and a quantization stage. As we can see in FIG. 1, a periodic sampler 11-2 samples the signal at uniform intervals (Referred to as sample times) to provide digital signal 11-3. The quantization's role is to convert the mentioned discrete values into bits.

Periodic samplers require highly accurate clock support, leading to a big consumption of energy. In practice it is very complicated to design precise clock samplers which work at a specific rate, and deviations could be involved. Asynchronous samplers provide a solution to the mentioned disadvantages, based on changes in the input signal instead of sampling at fixed intervals with the same length. These kinds of samplers are able to encode time intervals-Asynchronous ADCs (AADCs) sample signals non-uniformly, only when detecting specific events which may include amplitude information (for example, an “event” could be a moment in time where the integral of our biased signal crosses a given threshold). The time moments where we sample the signal are mostly called “fire times”.

This procedure is called “time encoding”. There is a clear correlation between the variance of the signal and the number of samples-a signal which experiments more variations, probably will require more samples, and vice versa.

Time encoding machines not only can function without the need of a clock but also can operate with low power consumption and their hardware implementation is very accessible compared to the synchronous approach. They offer an effective approach for AADC design and implementation, as well as a significant improvement in the quality of the recovered signal.

Several designs of time encoding have been proved, with the most outstanding of them being Integrate-and-Fire Time Encoding Machine (IF-TEM), Compressed Integrate-and-Fire Time-Encoding Machine (CIF-TEM) and Adaptive Integrate-and-Fire Time Encoding Machine (AIF-TEM).

### SUMMARY

According to an embodiment, there is provided a method for sampling an analog signal, the method includes preforming multiple sampling iterations to provide timing information that represents the analog signal at multiple points in time; wherein each sampling iteration includes adding an adaptive bias to the analog signal to provide a biased signal, wherein the adaptive bias is determined based on values of the analog signal during a set of previous sampling iterations; integrating the biased signal by an integrator to provide an integration result; comparing the integration result to a threshold; generating a timestamp when the integration result exceeds the threshold; and generating a representation of a difference between the current timestamp to last generated timestamp. The threshold may be determined in any manner—for example to provide a required quality and/or accuracy and the like

According to an embodiment, each sampling iteration comprises determining the adaptive bias based on an estimate of a maximal sampled value of the analog signal during the sampling iteration.

According to an embodiment, each sampling iteration comprises determining the adaptive bias based on variations in at least one of an amplitude and a frequency of the analog signal.

According to an embodiment, the generating of the representation comprises applying a fixed quantization.

According to an embodiment, the generating of the representation comprises applying a dynamic quantization that is responsive to an amplitude of the analog signal.

According to an embodiment, the generating of the representation comprises compressing the difference between the current timestamp to last generated timestamp.

According to an embodiment, the generating of the representation comprises dividing a variable that is indicative to a most significant portion and a least significant portion

According to an embodiment, the method also includes quantizing only the least significant portion and transmitting the most significant portion only when a value of the most significant portion differs from a last value of the most significant portion.

According to an embodiment, the dividing of the variable is based on an estimate of the maximal sampled value of the analog signal during the sampling iteration.

A non-transitory computer readable medium that stores instructions executable by a hardware sampler for sampling an analog signal, by: preforming multiple sampling iterations to provide timing information that represents the analog signal at multiple points in time; wherein each sampling iteration comprises: adding an adaptive bias to the analog signal to provide a biased signal, wherein the adaptive bias is determined based on values of the analog signal during a set of previous sampling iterations; integrating the biased signal by an integrator to provide an integration result; comparing the integration result to a threshold; generating a timestamp when the integration result exceeds the threshold; generating a representation of a difference between the current timestamp to last generated timestamp.

According to an embodiment, each sampling iteration comprises determining the adaptive bias based on an estimate of a maximal sampled value of the analog signal during the sampling iteration.

According to an embodiment, each sampling iteration comprises determining the adaptive bias based on variations in at least one of an amplitude and a frequency of the analog signal.

According to an embodiment, the generating of the representation comprises applying a fixed quantization.

According to an embodiment, the generating of the representation comprises applying a dynamic quantization that is responsive to an amplitude of the analog signal.

According to an embodiment, the generating of the representation comprises compressing the difference between the current timestamp to last generated timestamp.

According to an embodiment, the generating of the representation comprises dividing a variable that is indicative to a most significant portion and a least significant portion

According to an embodiment, the non-transitory computer readable medium further stores instructions executable by the hardware sampler for quantizing only the least significant portion and transmitting the most significant portion only when a value of the most significant portion differs from a last value of the most significant portion.

According to an embodiment, the dividing of the variable is based on an estimate of the maximal sampled value of the analog signal during the sampling iteration.

According to an embodiment, there is provided a hardware sample for sampling an analog signal, the hardware sampler comprises: one or more processing circuits that are configured to execute instructions that cause the one or more processing circuits to preform multiple sampling iterations to provide timing information that represents the analog signal at multiple points in time; wherein each sampling iteration comprises: adding an adaptive bias to the analog signal to provide a biased signal, wherein the adaptive bias is determined based on values of the analog signal during a set of previous sampling iterations; integrating the biased signal by an integrator to provide an integration result; comparing the integration result to a threshold; generating a timestamp when the integration result exceeds the threshold; and generating a representation of a difference between the current timestamp to last generated timestamp.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates an example of signals.

FIG. 2 illustrates an example of a sampler.

FIG. 3 illustrates an example of a sampler.

FIG. 4 illustrates an example of a sampler.

FIG. 5 illustrates an example of a compressor of the sampler of FIG. 4.

FIG. 6 illustrates an example of a sampler.

FIG. 7 illustrates an example of a sampler.

FIGS. 8-15 illustrate examples of results indicative of the properties of one or more samplers.

FIG. 16 illustrates an example of a method.

FIGS. 17-18 illustrate first, second and third tables.

### DETAILED DESCRIPTION OF THE DRAWINGS

Our main contributions in this project are as follows: We propose a new design that combines both the compression scheme and the adaptive approach of IF-TEM. We conducted numerical evaluations using synthetic randomized band-limited (BL) signals and a real audio signal. The results demonstrate that the proposed CAIF-TEM outperforms IF-TEM, CIF-TEM, and AIF-TEM. We also show that the CAIF-TEM outperforms CIF-TEM in terms of both Mean Squared Error (MSE) and total number of bits. During the whole project, we adopted the MSE as our main evaluation technique. We also investigated other critical parameters and concepts during the whole process such as oversampling, bits ratio between different machines, the compression ratio and much more.

According to an embodiment various quantization and/or compression method are used—for example:
a. Analog based—see for example—Y. Kim, D. Shon, and T. W. Kim, “A 0.008-mm2, 35-μW, 8.87-ps-resolution CMOS time to-digital converter using dual-slope architecture,” International Journal of Circuit Theory and Applications, vol. 45, no. 4, pp. 466-482, 2017
b. Counter based—see for example—J. M. Ingino and V. R. von Kaenel, “A 4-GHz clock system for a high-performance system on-a-chip design,” IEEE Journal of Solid-State Circuits, vol. 36, no. 11, pp. 1693-1698, 2001.
c. Delay line—see for example—R. Siddiqui, F. Yuan, and Y. Zhou, “A 500-MS/s 8.4-ps Double-Edge Successive Approximation TDC in 65 nm CMOS,” in 2019 IEEE 62nd International Midwest Symposium on Circuits and Systems (MWSCAS). IEEE, 2019, pp. 770-773
d. Pulse shrinking—see for example—P. Tutuani, E. Amankrah, and R. Geiger, “A high resolution capacitive-tuned delay pulse shrinking time to digital converter,” Authorea Preprints, 2024
e. Two-step pulse shrinking—see for example—R. Enomoto, T. Iizuka, T. Koga, T. Nakura, and K. Asada, “A 16-bit 2.0-ps Resolution Two-Step TDC in 0.18-μm CMOS Utilizing Pulse-Shrinking Fine Stage With Built-In Coarse Gain Calibration,” IEEE Transactions on Very Large Scale Integration (VLSI) Systems, vol. 27, no. 1, pp. 11-19, 2018
f. Another two-step-implementation—see for example—Y. J. Park and F. Yuan, “Two-step pulse-shrinking time-to-digital converter,” Microelectronics Journal, vol. 60, pp. 45-54, 2017

### Problem Formulation

Let x(t) be an analog c-bounded signal, lx(t)|≤c, where c is a real number: c∈ [symbol] . Moreover, the signal is 2Ω bandlimited (BL), meaning his Fourier transform is zero outside the closed interval [−Ω, Ω], where Ω is in radians per second. We assume the BL signals are with a finite energy. The energy E is given by:

$$E = {\int }_{- ∞}^{∞} {\vert x ( t ) \vert}^{2} dt < ∞ \qquad ( 1 )$$

We consider the problem of sampling and recovering x(t). We assume the following relation between the maximal amplitude c and the finite energy E, given the maximal biggest frequency of our bandwidth Ω(eq.2):

$$c = \sqrt{\frac{E Ω}{π}} \qquad ( 2 )$$

After the sampling process, we get a discrete set of encodement measurements for the fire times (recall: the times where the desired event involving the amplitude information happens). Those encoded measurements are quantized in order to produce bit representation. A direct implication of the quantization stage, symbolized by Q(⋅), is that the recorded quantized signal cannot be perfectly recovered due to quantization error.

Our main goal is to minimize the distortion between the original signal x(t) and the quantized reconstructed signal \hat{x}(t), ensuring precise recovery as good as possible. Distortion will be evaluated using MSE metric expressed in dB as follows(eq.3):

MSE[dB]≙10 log₁₀∥x(t)−\hat{x}(t)∥_{L}_{₂}_{[0,T]} i.(3)

### Theorical Section

There is provided a theoretical background about terms and time encoding machines that we will take into consideration while implementing our Integrate-Fire-Time encoding machine named CAIF-TEM (Compressive and Adaptive Integrate-Fire-Time encoding machine). Before forecasting the combined machine, it is essential to understand previous models such as the basic IF-TEM, as well as the separated machines: AIF-TEM and CIF-TEM. During the whole process, new ideas, concepts and definitions will be introduced.

### Periodic Sampler

The periodic sampler is a synchronous sampler and the most popular one. As can be seen in FIG. 1, periodic samplers involve the measurement of the signal's amplitude at uniform time intervals. Given an input analog signal x(t), the periodic sampler transforms it into a sequence of discrete values x (nTₛ),where n is an integer and Tₛ is called the periodic time of the sampler. In this case, the distance between two sampling points is constant and equal to Tₛ.

According to Shannon-Nyquist theorem, if x(t) is 2Ω-band limited (2Ω BL) signal in the frequency domain, and taking into assumption the non-existence of a quantizer, then x(t) can be perfectly reconstructed with zero distortion from its discrete values x (nTₛ). The theorem applies when

$${T}_{s} < \frac{Ω}{π} or equal to \frac{Ω}{π} .$$

This condition is sufficient, but not obligatory in order to ensure perfect reconstruction. Nevertheless, if we want to ensure perfect reconstruction for every given signal, it is needed. Otherwise, some signals will be reconstructed properly, and others do not, depending on the functional behavior of the Fourier transform of x(t), particularly the composition of the frequencies in the BW. For example, passband signals may be perfectly recovered also with a sampling time which does not necessarily match the Nyquist theorem original requirement.

### IF-TEM Sampler

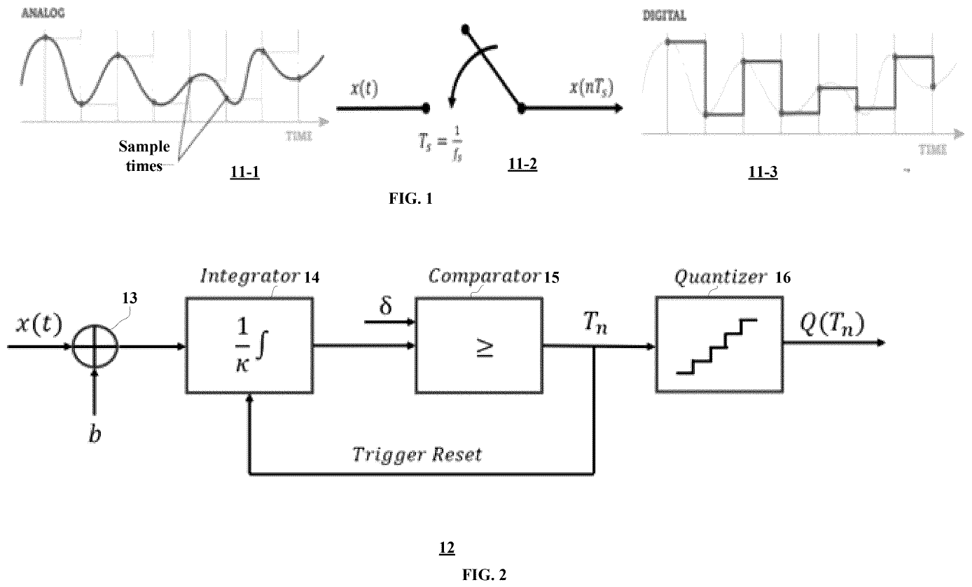

The IF-TEM is one of the most basic asynchronous samplers which belong to the Time Encoding Machine (TEM) family. It not only achieves better results than the periodic sampler, but also, its hardware is significantly simpler, as we can see in FIG. 2—illustrating encoder 12. IF-TEM first adds (using adder 13) a bias to ensure that the input signal is positive, then integrates (using integrator 14) the signal and encodes the times it crosses a given threshold (the comparison to a threshold is executed by comparator 15). Finaly, we quantize the samples using a K-level uniform quantizer (denoted Quantizer 16), where K=2^{N} and N represents the number of bits.

This sampler is characterized by the following parameters: bias b, threshold δ and scaling factor κ for the integrator. The input signal x(t) has finite energy. It is essential to choose a bias b which is greater than the maximum amplitude of the signal, i.e., |x(t)|≤c<b<∞. Otherwise, the integrator will not be a monotonic increasing function, thus there is a risk the threshold will never be achieved leading to the non-sampling of essential points. From FIG. 2 (illustrating IF-TEM sampler with quantization), we can conclude that before time encoding the signal x(t), we add the bias b, then multiply the result

$$b + x ( y ) by \frac{1}{κ} .$$

Continually we encode either the times we crossed the threshold [symbol] (fire times) or their differences Tₙ=tₙ₊₁−tₙ. After crossing the threshold δ, we record the relevant firing time, and then the integrator is reset to be zero. The integrator is given by (t≥tₙ):

$$y ( t ) {=}^{Δ} \frac{1}{κ} {\int }_{{t}_{n}}^{t} ( b + x ( τ ) ) d τ \qquad ( 4 )$$

When t=tₙ₊₁ the output y(t) is equal to δ:

$$\frac{1}{κ} {\int }_{{t}_{n}}^{{t}_{n + 1}} ( b + x ( τ ) ) d τ = δ ⇒ \qquad ( 5 )$$

$$\frac{1}{κ} {\int }_{{t}_{n}}^{{t}_{n + 1}} x ( τ ) d τ + \frac{b ( {t}_{n + 1} - {t}_{n} )}{κ} = δ \qquad ( 6 )$$

Recall −c≤x(t)≤c<b, we can get upper and lower bounds to the integral of the input signal,

$$- c ( {t}_{n + 1} - {t}_{n} ) \leq {\int }_{{t}_{n}}^{{t}_{n + 1}} x ( τ ) d τ \leq c ( {t}_{n + 1} - {t}_{n} ) .$$

### Therefore:

$$\frac{- c ( {t}_{n + 1} - {t}_{n} )}{κ} + \frac{b ( {t}_{n + 1} - {t}_{n} )}{κ} \leq δ \leq \frac{t ( {t}_{n + 1} - {t}_{n} )}{κ} + \frac{b ( {t}_{n + 1} - {t}_{n} )}{κ} \qquad ( 7 )$$

Recall Tₙ=tₙ₊₁−tₙ, we can write (7) in a simpler way:

$${T}_{n} ( \frac{b - c}{κ} ) \leq δ \leq {T}_{n} ( \frac{b + c}{κ} ) \qquad ( 8 )$$

Finally, we can conclude that Tₙ is bounded by the following values:

$$Δ {t}_{min} {=}^{Δ} \frac{κ δ}{b + c} \leq {T}_{n} \leq \frac{κ δ}{b - c} {=}^{Δ} Δ {t}_{max} \qquad ( 9 )$$

It is important to acknowledge that Nyquist condition is relevant to all samplers, whether they are synchronous or asynchronous. For the periodic sampler, the difference between two close points is constant and equal to

$${T}_{s} < \frac{π}{Ω} .$$

In our case, Tₙ is not constant. As a result, in order to ensure Nyquist condition, we will take the maximum

$${T}_{n} , Δ {t}_{max} < \frac{π}{Ω} .$$

Let us define the Nyquist rate as:

$${r}_{c} {=}^{Δ} \frac{κ δ}{b - c} \cdot \frac{Ω}{π} < 1 \qquad ( 10 )$$

The quantization step size is defined by:

$${Δ}_{IF - TEM} {=}^{Δ} \frac{Δ {t}_{max} - Δ {t}_{min}}{K} = \frac{κδ \cdot 2 c}{( b - c ) ( b + c ) K} \qquad ( 11 )$$

### AIF-TEM Sampler

The adaptive integrate-and-fire time-encoding-machine (AIF-TEM) is the adaptive version of the IF-TEM. It is a sampler which dynamically adapts to the amplitude and frequency variations of the input. As illustrated by the results section, the IF-TEM indeed achieves a reasonable MSE (in practice better than the periodic sampler). Nevertheless, similarly to the periodic sampler, it also has a constant Nyquist ratio r_{c}. As a result, it limits the performance of our sampler since our bias is set according to the worst case in order to fulfil Nyquist condition. According to equation (5), setting a constant b which complies with Nyquist condition but is also bigger than needed, may cause a disadvantage in our performance, since we get to the threshold δ more times provoking more samples. The adaptive model provides a brilliant solution to this problem. By dividing the time domain into separated ranges, for each range we can set a different bias b, which is set according to the range's maximum amplitude. For ranges where the maximum amplitude is smaller than the maximum amplitude of the entire input signal, we get a smaller bias, leading to less samples in the given range. Since this smaller bias still complies with Nyquist condition in this range, we can expect a perfect reconstruction (assuming the non-existence of a quantizer, which provokes quantization error).

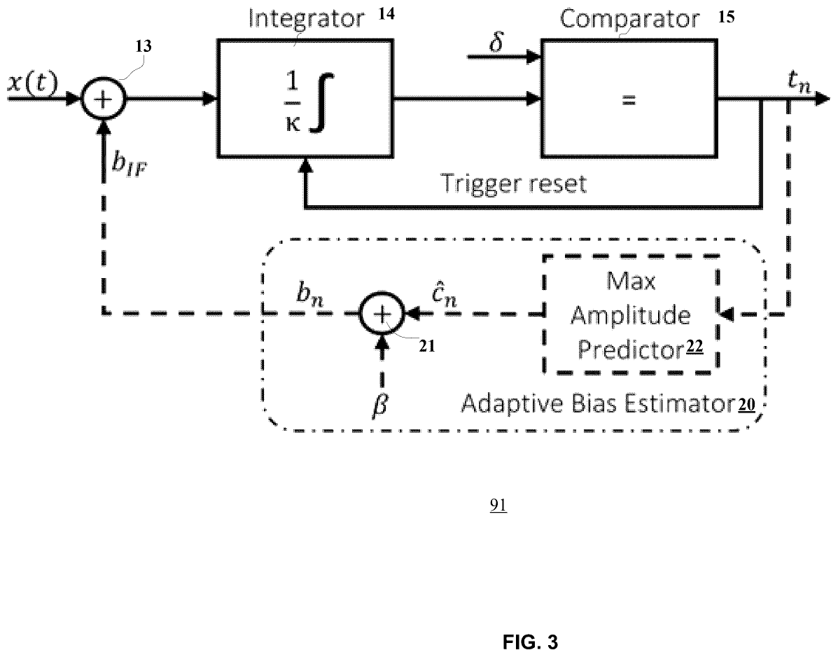

As we can see in FIG. 3 (AIF-TEM sampler without quantization), the AIF-TEM 91 includes a new block, Max Amplitude Predictor (MAP) 22 (that belongs to an adaptive bias estimator 20), which estimates amplitude variations to adaptively set the bias. The adaptive bias estimator 20 also includes another adder 21 that follows the max amplitude predictor 22

Examples of the MAP include using exponentially weighted moving average (EWMA), autoregressive with Exogenous Input (ARX) model, a Kalma filter, a recursive least square (RLS), and the like.

We can think about each range as a window of size ω. The time window is expanded from the current fire time tₙ back to the previous ω fire times until t_{n-ω}. According to these definitions, we can define the maximum amplitude in each range:

$${c}_{n} {=}^{Δ} {max}_{{t}_{n - ω} \leq t \leq {t}_{n}} \vert x ( t ) \vert \qquad ( 12 )$$

In order to adjust the bias bₙ (the bias that matches with cₙ), first, we need to estimate the value of cₙ, denoted by [symbol] . As we can see in FIG. 3, the MAP first predicts [symbol] then we add a positive constant β, to ensure that the bias is bigger than the maximum amplitude in the current window, leading to a monotonic increasing integrator:

bₙ= [symbol] +β (13)

The MAP block supports various implementations and algorithms. We chose the following method to estimate cₙ as presented in [1] which involves using IIR filter, as following:

$${z}_{n} {=}^{Δ} \vert - {b}_{n} + \frac{κ δ}{{T}_{n}} \vert \qquad ( 14 )$$

$$\text{?} {=}^{Δ} {α}_{1} {z}_{n} + ( 1 - {α}_{1} ) \text{?} \qquad ( 15 )$$

$$\text{?} {=}^{Δ} \text{?} + {α}_{2} {S}_{n} \qquad ( 16 )$$

Where α₁, α₂ are parameters that we are able to change according to our needs. Sₙ is the variance of [symbol] that we calculate via the Welford's method:

$${S}_{n}^{2} = \frac{1}{ω} {\sum }_{l = n - ω}^{n} {( \hat{{c}_{l}} - {μ}_{n} )}^{2} \qquad ( 17 )$$

$${μ}_{n} = \frac{1}{ω} {\sum }_{l = n - ω}^{n} \hat{{c}_{l}} \qquad ( 18 )$$

In order to ensure that the MAP block works properly the following condition must be met:

$$∀ β > 0 : {arg min}_{{b}_{n} ∈ [ \vert x ( t ) \vert + β , ∞ ]} {b}_{n} s . t . {b}_{n} \geq {c}_{n} + β , ∀ n ∈ ℤ \qquad ( 19 )$$

We must choose β that satisfies the Nyquist condition and oversampling rate (as will be defined later). Initially the bias b₁ is determined to be greater then cₘₐₓ.

Similarly to the IF-TEM's output definition of the integrator, we can define the following function for each t≥tₙ₋₁:

$${y}_{n} ( t ) {=}^{Δ} \frac{1}{κ} {\int }_{{t}_{n - 1}}^{t} ( {b}_{n} + x ( τ ) ) d τ \qquad ( 20 )$$

When t=tₙ, t>tₙ₋₁, we get the following equation:

$$\frac{1}{κ} {\int }_{{t}_{n - 1}}^{{t}_{n}} ( {b}_{n} + x ( τ ) ) d τ = δ \qquad ( 21 )$$

By doing the same mathematical analysis we can get upper and lower bounds for Tₙ:

$$Δ {t}_{min} [ n ] {=}^{Δ} \frac{κ δ}{{b}_{n} + {c}_{n}} \leq {T}_{n} \leq \frac{κ δ}{{b}_{n} - {c}_{n}} {=}^{Δ} Δ {t}_{max} [ n ] \qquad ( 22 )$$

Similarly to the counterpart definition in IF-TEM, we define the Nyquist ratio for AIF-TEM as following:

$${r}_{{a}_{n}} {=}^{Δ} \frac{κ δ}{{b}_{n} - {c}_{n}} \cdot \frac{Ω}{π} < 1 , ∀ n ∈ {S}_{{W}_{i}} \qquad ( 23 )$$

Where S_{w}_{ᵢ} includes all the samples tᵢ in each window Wᵢ=[t_{i_ω}, tᵢ].

The average oversampling rate (OS) for a 2Ω bandlimited signal is defined as:

$${f}_{s} {=}^{Δ} \frac{1}{𝔼 [ {T}_{n} ]} \qquad ( 24 )$$

$$OS {=}^{Δ} {f}_{s} \cdot \frac{π}{Ω} \qquad ( 25 )$$

The lower the OS, the less samples we have and so less bits we need to save. Therefore, we get a more efficient sampler. As illustrated by the results, the AIF-TEM's OS (OSₐ) indeed outperforms the IF-TEM's OS. As a result, the AIF-TEM achieves better performance for less samples. In that way we can also save more bits.

The AIF-TEM's OS upper bound (OSUₐ) is, according to Jensen's Inequality for the convex function

$$f ( x ) = \frac{1}{x} , x > 0 :$$

$${OS}_{a} = \frac{1}{𝔼 [ {T}_{n} ]} \cdot \frac{π}{Ω} \leq 𝔼 [ \frac{1}{{T}_{n}} ] \cdot \frac{π}{Ω} \qquad ( 26 )$$

We can conclude from equation 22, and estimation properties:

$$𝔼 [ \frac{1}{{T}_{n}} ] \cdot \frac{π}{Ω} \leq \frac{𝔼 [ {b}_{n} + {c}_{n} ]}{κδ} \cdot \frac{π}{Ω} = \frac{𝔼 [ {b}_{n} ] + 𝔼 [ {c}_{n} ]}{κδ} \cdot \frac{π}{Ω} \leq \frac{𝔼 [ {b}_{n} ] + {c}_{max}}{κδ} \cdot \frac{π}{Ω} {=}^{Δ} {OSU}_{a} \qquad ( 27 )$$

### Bit Comparison Between IF-TEM and AIF-TEM

Let v, be the ratio between the oversampling rate of IF-TEM and AIF-TEM, where

$$ν = \frac{OS}{{OS}_{a}} .$$

Let ρ be the number of bits used to encode the bias for each sample. Assuming a K-level dynamic uniform quantizer, the ratio of the total number of bits between IF-TEM and AIF-TEM is given by:

$${r}_{bits} = \frac{Total number of IF - TEM bits}{Total number of AIF - TEM bits} \qquad ( 28 )$$

Assume the total number of samples for AIF-TEM is Lₐ. According to OS's definition, the total number of samples for IF-TEM is νLₐ. As a result, the total number of bits used for IF-TEM is νLₐ log₂ K, and for AIF-TEM is Lₐ log₂ K+L_{α}β. Thus, r_{bits} is:

$${r}_{bits} = \frac{ν {L}_{a} {log}_{2} K}{{L}_{a} {log}_{2} K + {L}_{a} ρ} = \frac{{νlog}_{2} K}{{log}_{2} K + ρ} \qquad ( 29 )$$

In order to ensure that the total number of bits for IF-TEM is bigger than the total number of bits for AIF-TEM r_{bits} needs to be greater than 1.

$${r}_{bits} = \frac{{νlog}_{2} K}{{log}_{2} K + ρ} \geq 1 ⇒ \qquad ( 30 )$$

$${νlog}_{2} K \geq {log}_{2} K + ρ ⇒ \qquad ( 31 )$$

$$ν \geq 1 + \frac{ρ}{{log}_{2} K} \qquad ( 32 )$$

### CIF-TEM Sampler

The compressed integrate-and-fire time-encoding-machine (CIF-TEM) is a sampler that aims to decrease the number of bits required by compressing analogously the Tₙ samples before the quantization stage. The compression relies on subdividing the time encoded dynamic range outcomes into tighter subranges which are then quantized by K-level uniform quantizer, where K=2^{N} and N represents the number of bits. Taking into advantage the stationarity property, the samples are analogously compressed before the quantization. This allows the CIF-TEM to reduce the total number of bits and improve the MSE compared to IF-TEM, while using the same number of samples.

Examples of compression are illustrated in:
a. Y. J. Park and F. Yuan, Two-step pulse-shrinking time-to-digital converter,” Microelectronics Journal, vol. 60, pp. 45-54, 2017.
b. R. Szplet and K. Klepacki, “An FPGA-integrated time-to-digital converter based on two-stage pulse shrinking,” IEEE Transactions on Instrumentation and Measurement, vol. 59, no. 6, pp. 1663-1670, 2009.
c. R. Enomoto, T. Iizuka, T. Koga, T. Nakura, and K. Asada, “A 16-bit 2.0-ps Resolution Two-Step TDC in 0.18-μm CMOS Utilizing Pulse-Shrinking Fine Stage With Built-In Coarse Gain Calibration,” IEEE Transactions on Very Large Scale Integration (VLSI) Systems, vol. 27, no. 1, pp. 11-19, 2018.

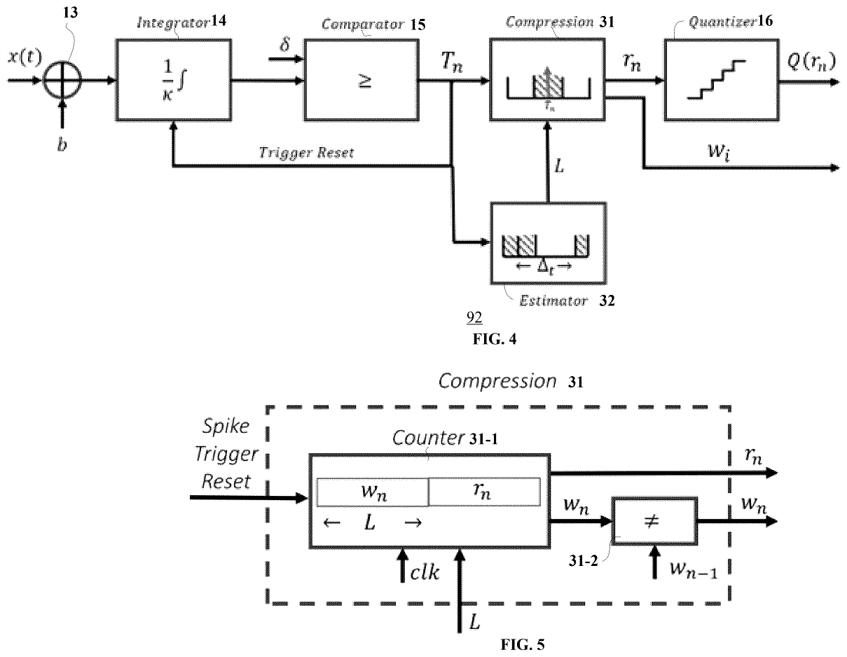

The CIF-TEM scheme with quantization is shown in FIG. 4 and the compression unit is illustrated in FIG. 5.

Recall that Tₙ is bound and its range is

$$[ \frac{κδ}{b + c} , \frac{κδ}{b - c} ] .$$

There are two methods for dividing this range. The first is to choose a constant number of windows (CCIF-TEM), and the second is to dynamically choose the number of windows (DCIF-TEM).

### CCIF-TEM Sampler

This method requires the assumption that the statics of Tₙ are known in advance. Mainly assume that μ (the mean) and σ (the variance) of Tₙ are given. This allows us to determine the constant number of windows to use:

$$L = ⌈ \frac{Δ {t}_{max} - Δ {t}_{min}}{2 \sqrt{σ}} ⌉ \qquad ( 33 )$$

Where Δtₘₐₓ, Δtₘᵢₙ were introduced in equation 9.

In FIG. 4 (illustrating sampler 92) adder 13 is followed by integrator 14 that is followed by comparator 15. The comparison result (signal Tₙ) is provided th the integrator 14, to a compressor 31 and an estimator 32. The estimator output an estimate L to the compressor. A first output signal of the compressor (rₙ) is provided to quantizer 16. A second output signal of the compressor (wᵢ) is provided as another output of the CIF-TEM.

As we can see in FIG. 4, the estimator block's main purpose is to calculate L. L is fed to the compressor 31. This leads to the compression block which has two entries, Tₙ and L. The compression block (FIG. 5) first divides the range of Tₙ to L windows and then finds the location of the sample in the subrange. This block includes a counter, a comparator and a clock. The two exits of this block are rₙ and ωₙ. ωₙ is the number of the window and is represented by the L MSB of the counter. For each sample we save the value of ωₙ only if it is different than the last, ωₙ≠ωₙ₋₁·rₙ is the location of the sample inside the window represented by the remaining bits (the LSB of the counter). FIG. 5 illustrates the compressor 31 as including a counter 31-1 followed by another comparator 32-1 that compares wₙ to w_{n_1}.

The quantization step of CCIF-TEM is given by:

$${Δ}_{CCIF - TEM} {=}^{Δ} \frac{{Δ}_{IF - TEM}}{L} = \frac{κδ \cdot 2 c}{( b - c ) ( b + c ) LK} \qquad ( 34 )$$

Since L≥1 then Δ_{CCIF-TEM}≤Δ_{IF-TEM}.

### DCIF-TEM Sampler

In the real world it is almost impossible to know the statistics of our input signal and Tₙ in advance, in practice we need to estimate the variance \hat{σ} and the mean \hat{μ} of Tₙ based on previous samples in real time. This allows us to adjust L accordingly. The mentioned method is called dynamic compression (DCIF-TEM). The system is initiated with a default value for L.

For the next L values, we estimate the variance and the mean according to the variance of the previous m>1 number of samples. Let [symbol] be the average of the last m samples of Tₗ, l∈[n−m+1, n]:

$$\text{?} {=}^{Δ} \frac{1}{m} {\sum }_{l = n - m + 1}^{n} {T}_{l} \qquad ( 35 )$$

The estimated variance is:

$$\hat{σ} {=}^{Δ} \frac{1}{m} {\sum }_{l = n - m + 1}^{n} {( {T}_{l} - \text{?} )}^{2} \qquad ( 36 )$$

So, the number of windows L is calculated in the same way as in CCIF-TEM:

$$L = ⌈ \frac{Δ {t}_{max} - Δ {t}_{min}}{2 \sqrt{\hat{σ}}} ⌉ \qquad ( 37 )$$

The quantization step size is calculated identically to the CCIF-TEM's quantization step size:

$${Δ}_{DCIF - TEM} {=}^{Δ} \frac{{Δ}_{IF - TEM}}{L} = \frac{κδ \cdot 2 c}{( b - c ) ( b + c ) LK} \qquad ( 38 )$$

Since L≥1 then Δ_{DCIF-TEM}≤Δ_{IF-TEM}.

Since L changes every sample and computed based on the previous m samples, the quantization step size changes. However, since the samples are stationary, we expect L to not change dramatically. It will only change if 8 value has big fluctuations, leading to a “constant” quantization step size.

Due to the fact that in CCIF-TEM we have an advanced knowledge of the signal statistics in contrast to DCIF-TEM, we may expect better performance in terms of MSE.

Finally, based on equations 11,34,38, which provide the formulas for quantization step sizes, in order to achieve the same step size in DCIF-TEM, CCIF-TEM, and in IF-TEM, we must change the quantizer in DCIF-TEM and CCIF-TEM with a K′ level uniform quantizer, where K′L=K, and N′=log₂ K′. A direct implication of this is that in order to achieve the same result in the IF-TEM we need additional bits.

### Proposed Solution Section: CAIF-TEM

There is provided a proposed compressed and adaptive integrated-and-fire-time-encoding machine (CAIF-TEM), a novel machine that not only dynamically adapts to the amplitude and frequency variations of the input but also contains an analog compression design before the quantization stage.

Our main contribution in the project is the combination between compressed design introduced and AIF-TEM.

We focused on the following configuration: first sampling the signal with the AIF-TEM and then compressing the result with analog compression methods using the same estimator and counter blocks from CIF-TEM.

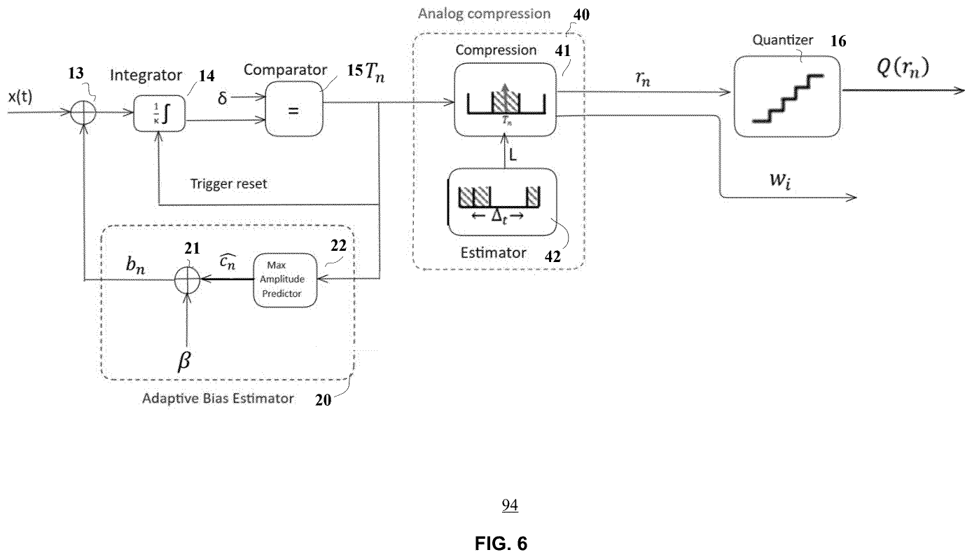

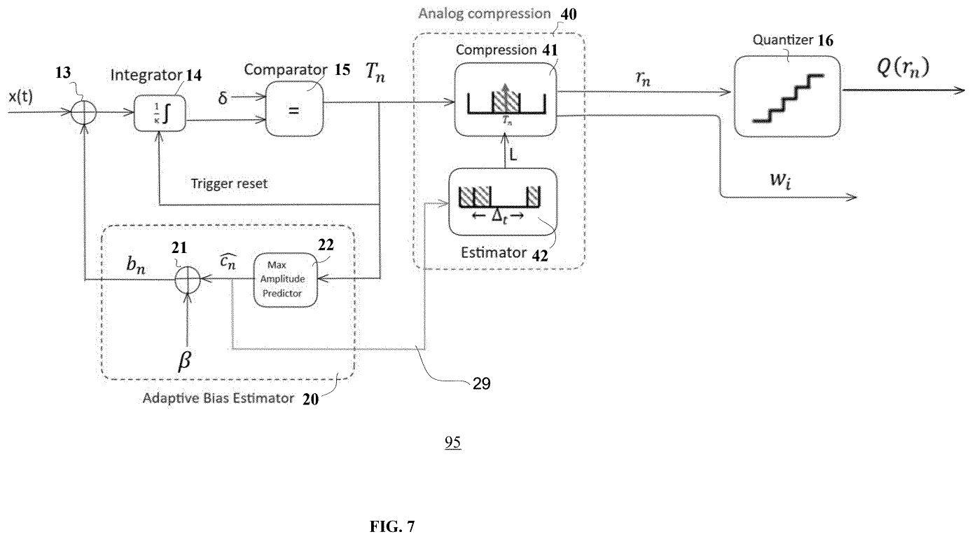

The general scheme for CAIF-TEM sampler (denoted 94) with quantization is given in FIG. 6. FIG. 6 illustrates sampler 94 that includes an adder 13 that is followed by integrator 14 that is followed by comparator 15. The comparison result (signal Tn) is provided th the integrator 14, to a compressor 31 and an estimator 32. The estimator output an estimate L to the compressor. A first output signal of the compressor (rₙ) is provided to quantizer 16. A second output signal of the compressor (wᵢ) is provided as another output of the sampler 94. The sampler 94 also includes an adaptive bias estimator 20 that includes max amplitude predictor 22 followed by another adder. The output of the adaptive bias estimator 20 is an adaptive bias that is fed to adder 13.

By adjusting the parameters of the system, the signal generation method and recovering process which are compatible with the compressed system and also with the adaptive system, we may see the benefits of the combined system compared to the separated systems. As illustrated by the results and the simulations, the MSE of the combined system will indeed be even better than the MSE of AIF-TEM and CIF-TEM.

The selection of the parameters and the way we generate and reconstruct the signals is crucial in order to enjoy the benefits of CAIF-TEM.

Recall we have two ways to think about the compressive approach: the constant approach and the dynamic approach. Accordingly, from now until the end of the paper, we denote two new names for the combined machine:
a. CCAIF-TEM (Constant-Compressed and Adaptive time encoding machine)
b. DCAIF-TEM (Dynamic-Compressed and Adaptive time encoding machine)

Similarly to CCIF-TEM, the number of windows for the compression, L, in CCAIF-TEM is calculated as:

$$L = ⌈ \frac{Δ {t}_{max} - Δ {t}_{min}}{2 \sqrt{σ}} ⌉ .$$

Analogically, the parallel to DCIF-TEM in our case (DCAIF-TEM) is:

$$L = ⌈ \frac{Δ {t}_{max} - Δ {t}_{min}}{2 \sqrt{\hat{σ}}} ⌉ .$$

Note that Δtₘₐₓ[n], Δtₘᵢₙ[n] as defined in equation (22) in AIF-TEM are based on the value of cₙ, that we can only estimate. Therefore, in our calculations we took into consideration the worst-case scenario, Δtₘₐₓ, Δtₘᵢₙ.

There are other possible ways to calculate L. Since in the adaptive sampling process we estimate the variance of cₙ, it is intriguing to use that estimation to calculate L. In that way, there is no need to estimate the variance of Tₙ. Recall equation (21):

$$\frac{1}{κ} {\int }_{{t}_{n - 1}}^{{t}_{n}} ( {b}_{n} + x ( τ ) ) dτ = δ ⇒ {\int }_{{t}_{n - 1}}^{{t}_{n}} ( x ( τ ) ) d τ + {b}_{n} \cdot {T}_{n} = κδ ,$$

when the last relationship is obtained from the linearity of the integral. From the mean value theorem for integrals, assuming x(t) is a continuous signal, we can assure the existence of sₙ∈[tₙ₋₁, tₙ] such as:

$${\int }_{{t}_{n - 1}}^{{t}_{n}} ( x ( τ ) ) d τ = x ( {s}_{n} ) \cdot ( {t}_{n} - {t}_{n - 1} ) .$$

### Therefore:

$$( x ( {s}_{n} ) + {b}_{n} ) \cdot {T}_{n} = κδ ⇒ {T}_{n} = \frac{κδ}{{b}_{n} + x ( {s}_{n} )} .$$

We can conclude that there is a strong correlation between bₙ and Tₙ. As a result, we can try a new way to calculate L:

$$L = 2 \cdot ⌈ \frac{{b}_{max} - {b}_{min}}{\sqrt{\text{?} \text{?}}} ⌉ \qquad ( 39 )$$

When

$${b}_{max} = {c}_{max} + β , {b}_{min} = β , {c}_{max} = \sqrt{\frac{EΩ}{π}} , \text{?} ( \text{?} ) = {S}_{n}^{2}$$

(see equations (17,18)). This formula comes from the fact that the MAP block in the AIF-TEM selects biases value in a segmented manner with a step size Δb, so we can utilize this and the relation between times and bias mentioned before, to calcualte the number of windows for time differnces in a different way. Such that considering number of windows for bias values is:

$${L}_{b} = ⌈ \frac{{b}_{max} - {b}_{min}}{\sqrt{\text{?} \text{?}}} ⌉ .$$

Then the number of windows for time differences is multiplied by 2: L=2·L_{b}. Similarly to DCAIF-TEM, the number of window changes dynamically, but based on the variance of the estimation of the amplitude instead of the variance of the time difference.

FIG. 7 illustrates CAIF-TEM-V2 sampler with quantization.

FIG. 7 illustrates sampler 95 that includes an adder 13 that is followed by integrator 14 that is followed by comparator 15. The comparison result (signal Tn) is provided th the integrator 14, to a compressor 31 and an estimator 32. The estimator output an estimate L to the compressor. A first output signal of the compressor (rₙ) is provided to quantizer 16. A second output signal of the compressor (wᵢ) is provided as another output of the sampler 94. The sampler 95 also includes an adaptive bias estimator 20 that includes max amplitude predictor 22 followed by another adder. The output of the adaptive bias estimator 20 is an adaptive bias that is fed to adder 13. The samples also includes a feedback 29 from the output of the max amplitude predictor 22 (signal [symbol] ) to the estimator 42.

As we can infer from the formula, in contrast to the original calculation of L which was based on Δtₘₐₓ, Δtₘᵢₙ, in the new method there is a clear dependency on the bias and [symbol] . Since the bias and [symbol] are crucial in the adaptive approach, we may expect better results than all the previous machines. The combined machine using the mentioned approach will be denoted DCAIF-TEM-V2.

Moreover, it is important to acknowledge that both in CIF-TEM and CAIF-TEM, the analog compression occurs after the sampling process. As a result, we can conclude that there is no correlation between the compression process and the oversampling rate since the oversampling is based on the statistics of Tₙ. Therefore, the oversampling rate of the combined machine (OS_{ca}), for any practical purpose, is the same as in the adaptive machine (OSₐ): OS_{ca}≅OSₐ. As defined above, the oversampling ratio

$$v = \frac{OS}{{OS}_{a}} ,$$

where OS is the oversampling rate of IF-TEM, is maintained for the combined system:

$$v = \frac{OS}{{OS}_{a}} ≅ \frac{OS}{{OS}_{ca}} \qquad ( 40 )$$

Let η it be defined as the number of bits needed to represent the window number:

η=┌log₂L┐ (41)

Let M be the total number of times where the window changes between consecutive samples. Recall, ρ, defined as the number of bits used to encode the bias. Assuming a K-level dynamic uniform quantizer, the ratio of the total number of bits between IF-TEM and CAIF-TEM is given by:

$${r}_{bits} = \frac{Total number of IF - TEM bits}{Total number of CAIF - TEM bits} \qquad ( 42 )$$

Recall Lₐ as the total number of samples for AIF-TEM, which is of course equal to the total number of samples for CAIF-TEM, since the analog compression stage does not influence the sampling process of the input signal. Therefore, the total number of samples for IF-TEM is vLₐ, and the total number of bits used for IF-TEM is νLₐ log₂ K. The total number of bits for the combined machine is Lₐ log₂ K+Lₐρ+ηM. Thus, r_{bits} is:

$${r}_{bits} = \frac{{vL}_{a} {log}_{2} K}{{L}_{a} {log}_{2} K + {L}_{a} ρ + η M} \geq \frac{{vL}_{a} {log}_{2} K}{{L}_{a} {log}_{2} K + {L}_{a} ρ + η {L}_{a}} \qquad ( 43 )$$

Where the inequality is true due to the fact that the number of samples cannot be smaller than the number of changes between windows: M≤Lₐ. We get the following after dividing by Lₐ both in denominator and nominator:

$${r}_{bits} \geq \frac{v {log}_{2} K}{{log}_{2} K + ρ + η} \qquad ( 44 )$$

A possible way to ensure that the combined system uses less bits than IF-TEM, is the following condition:

$$\frac{v {log}_{2} K}{{log}_{2} K + ρ + η} \geq 1 ⇒ \qquad ( 45 )$$

$$v {log}_{2} K \geq {log}_{2} K + ρ + η ⇒ \qquad ( 46 )$$

$$v \geq 1 + \frac{ρ + η}{{log}_{2} K} \qquad ( 47 )$$

Note that η is not a property of the system, in contrast to v, K, ρ. η depends on the input signal. Nevertheless, in practice its typical value rounds between 3 and 4 bits.

For the same reasons mentioned regarding the influence of the compressed components to the oversampling of the combined system, the Nyquist ratio also does not change for any valid application and there is no need to define it again, rₐ_{ₙ}≅r_{ca}_{ₙ}.

### Results Section

There are provide some simulation results which visualize the comparison between the different machines. We will compare the performances of the machines in terms of MSE, OS and total number of bits that are utilized. We will demonstrate that the combined machine improves the performance of the previous machines.

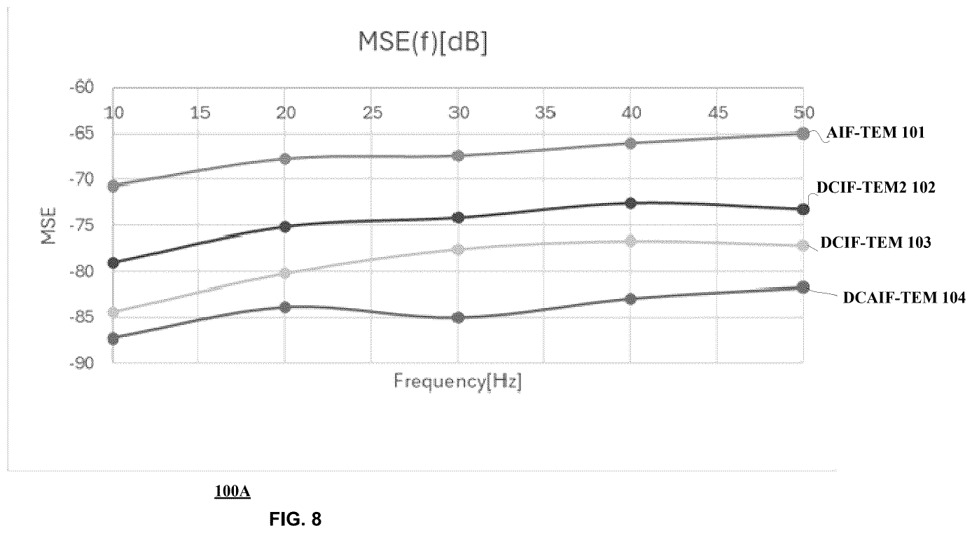

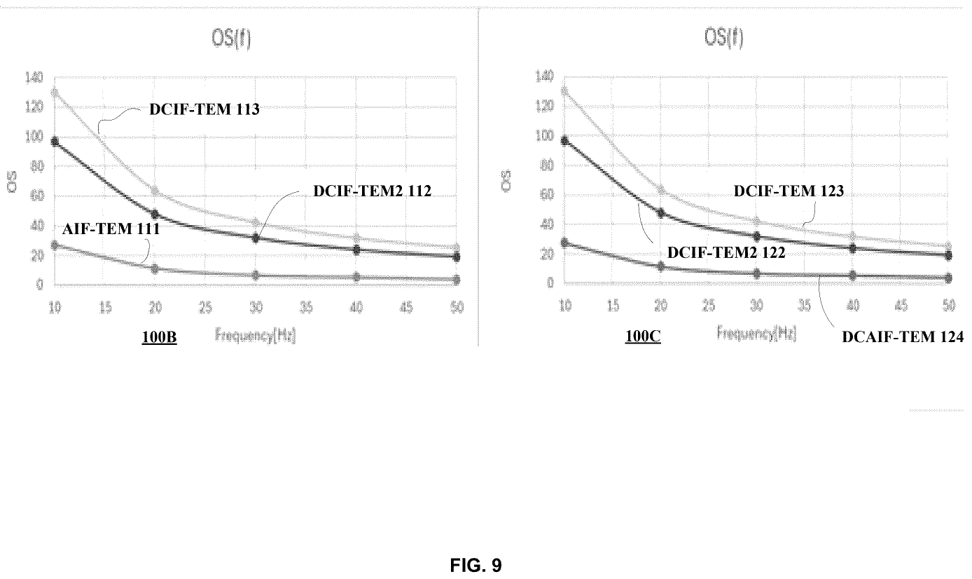

According to our assumptions, the simulations were done with input signals which are bounded, bandlimited and with finite energy. To best demonstrate the advantages of the system, for the first simulations, in FIG. 8, (including graphs 100A with linear arrangements 101, 102, 103 and 104) and FIG. 9 (including graph 100B with linear arrangements 111, 112 and 113, and graph 100C with linear arrangements 121, 122 and 123), we will use a 2Ω−BL cₘₐₓ-bounded signal with finite energy E. In our case, as shown in equation (2), cₘₐₓ=\sqrt{(EΩ)/π}, and Ω oscillates between 2π(10-50)Hz. The input signal is given by:

$$x ( t ) = {\sum }_{n = - M}^{M} a [ n ] \frac{sin ( Ω ( t - n \frac{π}{Ω} ) )}{Ω ( t - n \frac{π}{Ω} )} \qquad ( 48 )$$

Where M=2, t∈ [symbol] , and coefficients a[n] are randomly selected 50 times from [−1,1]. Energy E varies with frequency in [0.25,2.5].

We configure b_{IF}=cₘₐₓ+β, while ensuring that we fulfil the Nyquist condition, as presented in the theory section, i.e.,

$${r}_{c} = \frac{κδ}{{b}_{IF} - {c}_{max}} \cdot \frac{Ω}{π} < 1.$$

We chose the following values: β=0.1, δ=0.0156, κ=0.06. Therefore, in the worst-case scenario where Ω=2π·50 Hz, we get r_{c}=0.936<1. For CAIF-TEM, ∀n, r_{ca}_{ₙ}≤r_{c}, with ω=1. Later on in this section we will also introduce audio signals.

In the MAP block, which uses the Welford method as described in the theory section, we decided to choose the parameters: α₁=0.98, α₂=0.6.

In FIG. 8 (MSE with Respect to Frequency) we can see the average MSE, as defined in equation (3) in the theoretical section, of the different machines with respect to the frequency Ω, using a 10-level bit dynamic uniform quantizer.

Using the same parameters, in FIG. 9 (Oversampling with Respect to Frequency) we can see the average OS, as defined in equation (25) in the proposed solution section, of the different machines with respect to the frequency Ω, using a 10-level bit dynamic uniform quantizer.

In FIG. 8 we can clearly see that the combined machine (DCAIF-TEM) outperforms the other machines, for any given frequency (AIF-TEM, DCIF-TEM, DCIF-TEM2). There is a monotonic increasing tendency for all the machines with respect to the frequency—the bigger the frequency, the bigger the MSE and vice versa. The improvement in the MSE of the practical combined machine compared to the adaptive model is around 10-14 [dB], depending on the frequency.

The improvement in the MSE of the practical combined machine compared to the practical compressed model is around 3-8 [dB], depending on the frequency. Nevertheless, the DCIF-TEM has a much larger oversampling (see FIG. 9), meaning that a significantly higher number of samples are required. As a result, the compressed machine needs more memory to achieve these results. In order to illustrate the tradeoff between OS and MSE, we decided to analyze another DCIF-TEM (DCIF-TEM2) with the same parameters but 6, which was incremented by 33%.

It is important to acknowledge, as we mentioned in the theory section, that for any practical purpose, the analog compression does not influence the value of the oversampling. All the machines which include an adaptive bias achieve a similar OS rate, which is much lower than the OS rate of the machines with fixed bias. FIG. 9 illustrates all those insights.

Moreover, FIG. 9 demonstrates a monotonic decreasing behavior, matching the definition of the average oversampling in the theory section, equation (25).

Finally, these simulations illustrate a clear tradeoff between MSE and oversampling. Recall equation (25):

$$OS = \frac{1}{𝔼 [ {T}_{n} ]} \cdot \frac{π}{Ω} .$$

For any given frequency, there is an inverse correlation between [symbol] [Tₙ] and OS. A higher OS leads to a lower [symbol] [Tₙ], meaning that in average the difference between two neighboring samples is smaller, resulting in more samples in a given time segment. With a high probability, a bigger number of samples will improve the reconstruction prosses, causing directly a lower MSE.

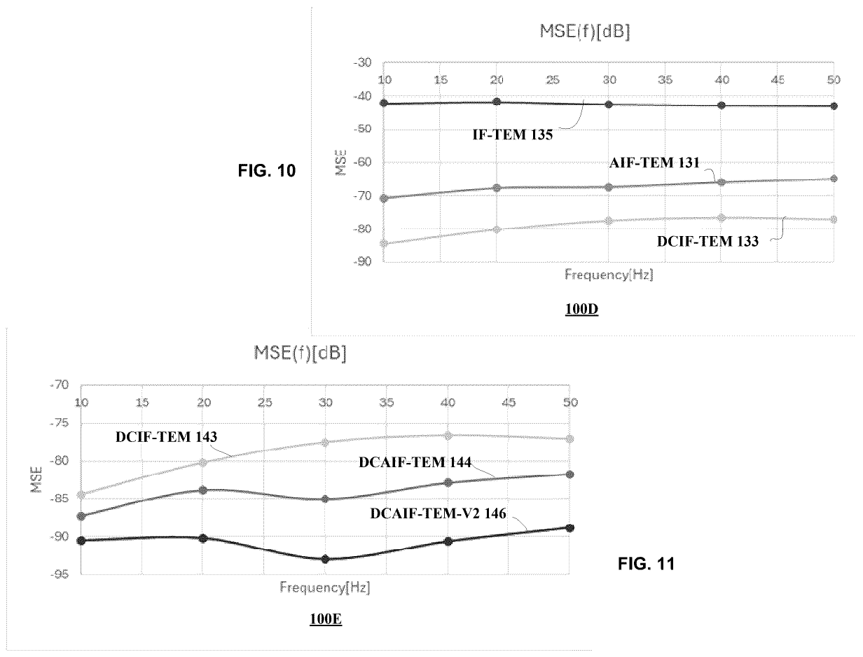

FIG. 10 is a figure which contains the same AIF-TEM and CIF-TEM from FIG. 8 and also IF-TEM. We preferred to not include IF-TEM in FIG. 8 with all the other graphs because its MSE is significantly the highest compared to the other machines, leading to a non-ideal resolution in the graph. In that way, both in FIG. 8 and FIG. 10 (MSE with Respect to Frequency—IF-TEM) the MSE differences are more visible and notable.

Note that according to FIG. 10, the basic IF-TEM model (linear arrangement 135 of graph 100D) achieves a higher MSE, then the other machines linear arrangements 131 and 133), as expected.

In FIG. 11 (MSE with Respect to Frequency—DCAIF-TEM-V2—linear arrangement 146 of graph 100E) we took the same combined machine from FIG. 8 and wanted to illustrate just the differences between it and the second version of the combined machine (different formula for L with the biases). Other linear arrangements 143 and 144 represented DCIF-TEM and DCAIF-TEM, respectively.

We can see that DCAIF-TEM-V2 outperforms DCAIF-TEM, meaning that it is the best TEM machine we have investigated during the project. It is important to mention that DCAIF-TEM-V2 uses a slightly different adaptive approach. Nevertheless, the essence and implementation are almost the same. Since the main contribution of the adaptive model is to improve the sampling process, the over-samplings are quite similar but are very close for any practical purpose.

In the second set of simulations, to best showcase the advantages of the system, we used similar input signal and parameters, except for the following changes: the input signal was generated like in the equation (48), but with M=5, differentially to the previous simulations. The system parameters that are different are a constant Ω=2π·10 Hz, and κ=0.24, leading to a Nyquist rate of r_{c}=0.7488<1. For CAIF-TEM, ∀n, r_{ca}_{ₙ}≤r_{c}, with ω=5.

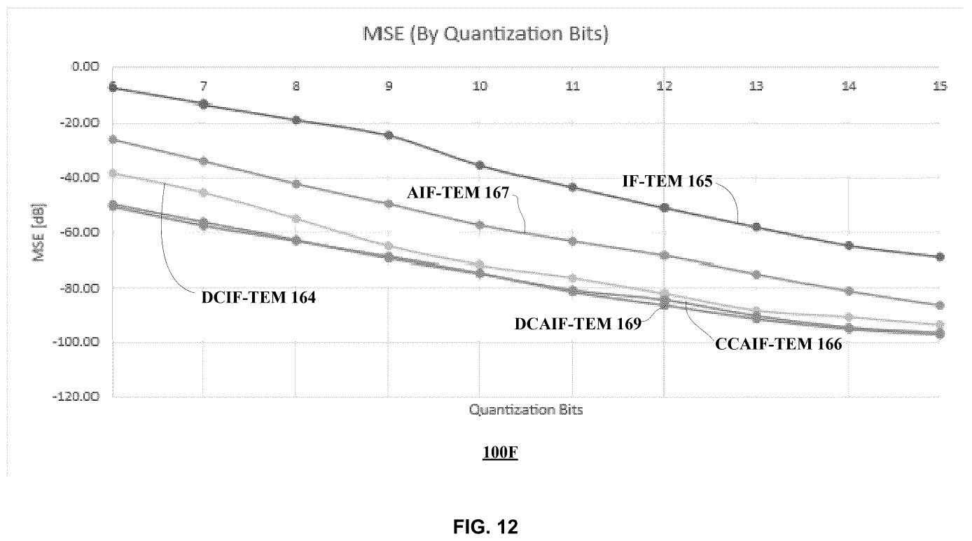

In FIG. 12 (MSE with respect to # of quantization bits) we can see the average MSE, as defined in equation (3) in the theoretical section, of the different machines with respect to K, with a K-level bit dynamic uniform quantizer. Graph 100F of FIG. 12 includes linear arrangements 164, 165, 166, 167 and 169.

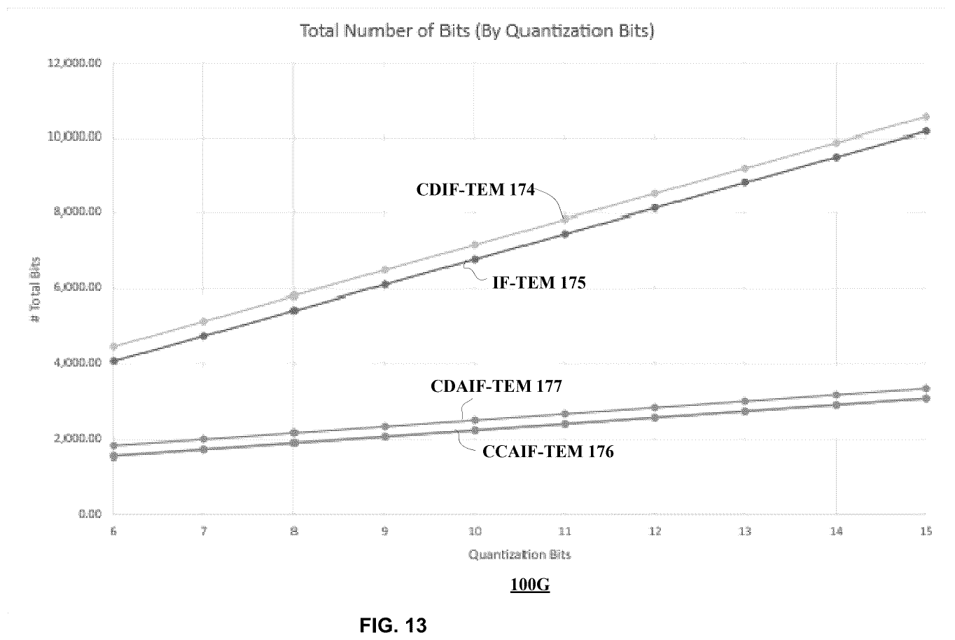

Using the same parameters, in FIG. 13 we can see the average Total number of bits used of the different machines with respect to K, with a K-level bit dynamic uniform quantizer. Graph 100G of FIG. 13 includes linear arrangements 174, 175, 176 and 177.

TABLE 1
Overall System Compression

| | | | Overall System | | Overall System | |
|---|---|---|---|---|---|---|
| | | | Compression | | Compression | |
| | | | [%] - Compared | | [%] - Compared | |
| Quantization bits | | | to A-IF-TEM | | to IF-TEM | |
| CA-IF- | A-IF- | | CCA-IF- | DCA-IF- | CCA-IF- | DCA-IF- |
| TEM | TEM | IF-TEM | TEM | TEM | TEM | TEM |
| 6 | 9 | 12 | 24.44% | 11.31% | 80.89% | 77.56% |
| 7 | 10 | 13 | 22.60% | 10.47% | 80.41% | 77.34% |
| 8 | 11 | 14 | 21.01% | 9.76% | 80.008% | 77.15% |
| 9 | 12 | 15 | 19.14% | 9.14% | 79.65% | 76.99% |
| 10 | 13 | — | 18.45% | 8.61% | — | — |
| 11 | 14 | — | 17.39% | 8.13% | — | — |
| 12 | 15 | — | 16.45% | 7.71% | — | — |

FIG. 12 shows that the combined machines (CCAIF-TEM, DCAIF-TEM) achieve a better MSE compared to all the other machines (IF-TE, AIF-TEM, DCIF-TEM). There is a monotonic decreasing tendency for all the machines with respect to the number of quantization bits—a bigger quantity of quantization bits leads to a better MSE, and vice versa. The improvement in the MSE of the practical combined machine compared to the adaptive model is around 10-24 [dB], depending on the number of quantization bits used.

The maximal improvement in the MSE of CAIF-TEM compared to DCIF-TEM is around 11 [dB], and becomes lower as we increase the number of quantization bits. When the number of quantization bits is very high (in our case 15), the MSE values of the compressed machine without an adaptive bias converges to the MSE of the combined machines. However, to achieve this matching MSE the compressed machine requires about 3 times as many total numbers of bits (see FIG. 13), meaning a much higher use of memory.

Note that IF-TEM (in blue) has significantly worse performance compared to the other machines, as expected.

FIG. 13 depicts the total number of bits used by the machines, which include the number of bits for each sample (log₂ K), the number of bits needed to encode the bias (ρ), and the number of bits needed for the compression windows (η), as presented in the results section. We can clearly see that indeed, the IF-TEM uses a remarkably higher total number of bits compared to the combined machine, meaning that our parameter's selection was successful.

Another conclusion we can infer from FIG. 13 is that the machines which include an adaptive bias require a significantly lower quantity of total bits. This insight can also be shown in table 1. The table demonstrates the percentage of total bits compression for an equal MSE, comparing the combined system to the adaptive system. For example, for MSE of −69 [dB], we need 12 quantization bits in AIF-TEM and 9 quantization bits in the combined machine. For the theoretical machine we have 16-24% compression, and for the practical machine 7-11% compression.

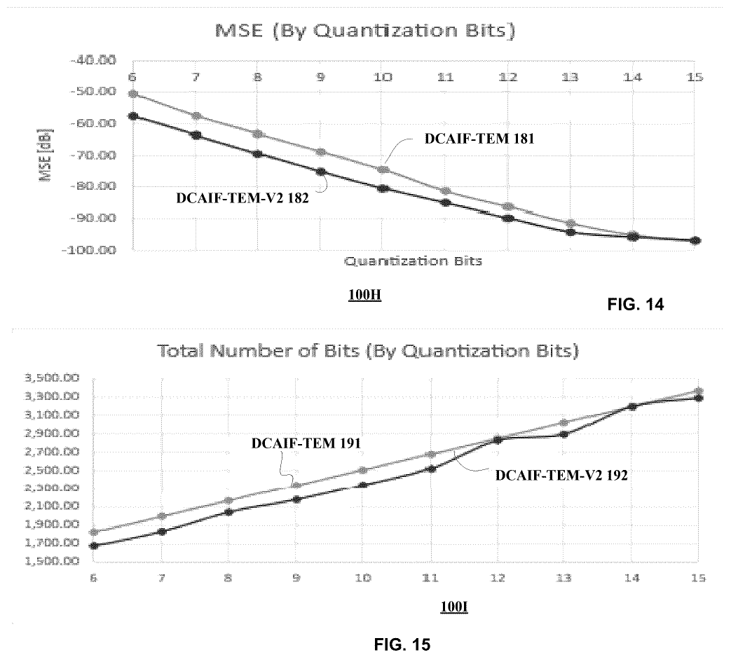

Finaly, we also compared DCAIF-TEM and DCAIF-TEM-V2 in terms of MSE (FIG. 14) and total number of bits (FIG. 15). Similarly to the frequency simulations, DCAIF-TEM-V2 also achieves better results as we can see in FIG. 14 (DCAIF-TEM vs DCAIF-TEM-V2). Graph 100H of FIG. 14 includes linear arrangements 181 and 182.

Lastly, we tested the performances of our machines with audio input signals. By choosing a proper configuration of parameters, also here we achieved better results in the combined machine. According to our assumptions, the simulations were done with input signals which are bounded, bandlimited and with finite energy. Graph 100I of FIG. 14 includes linear arrangements 191 and 192.

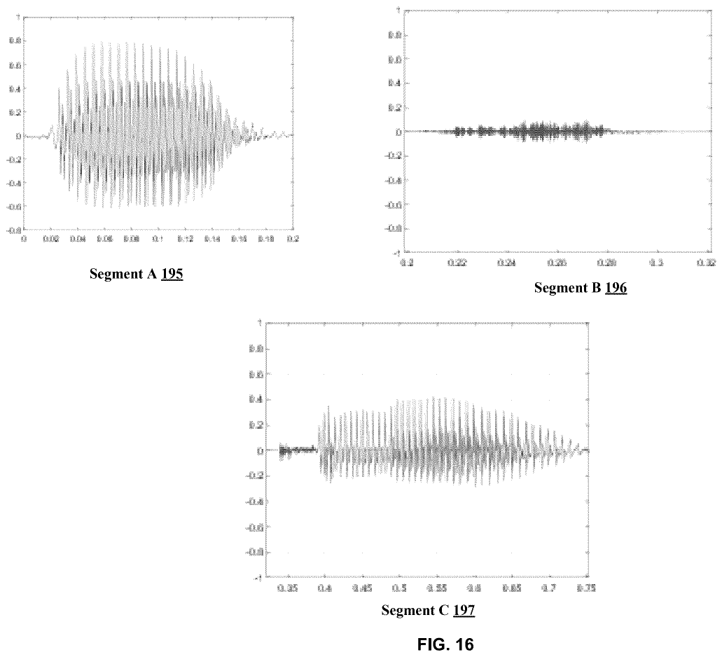

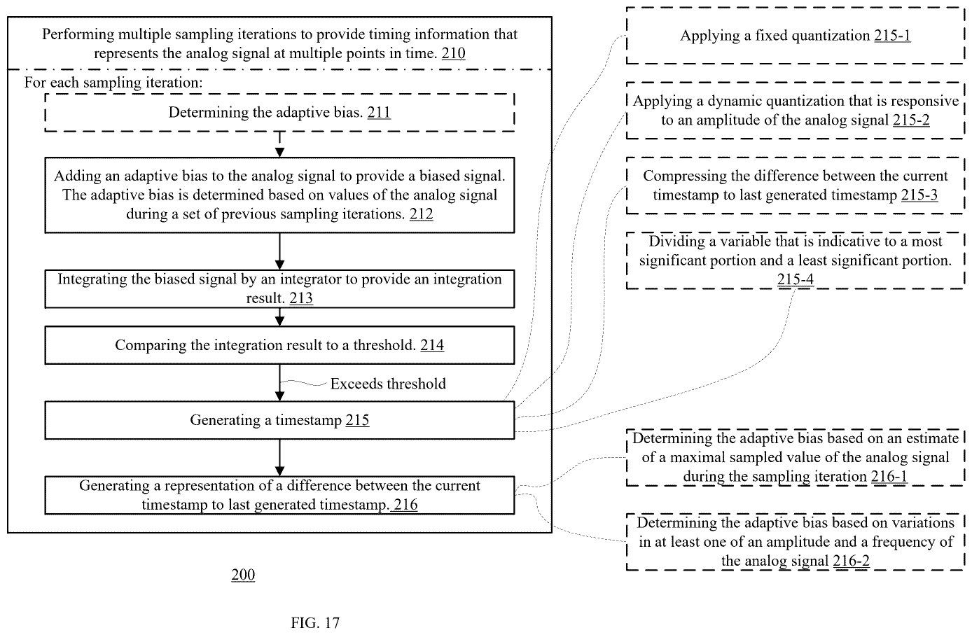

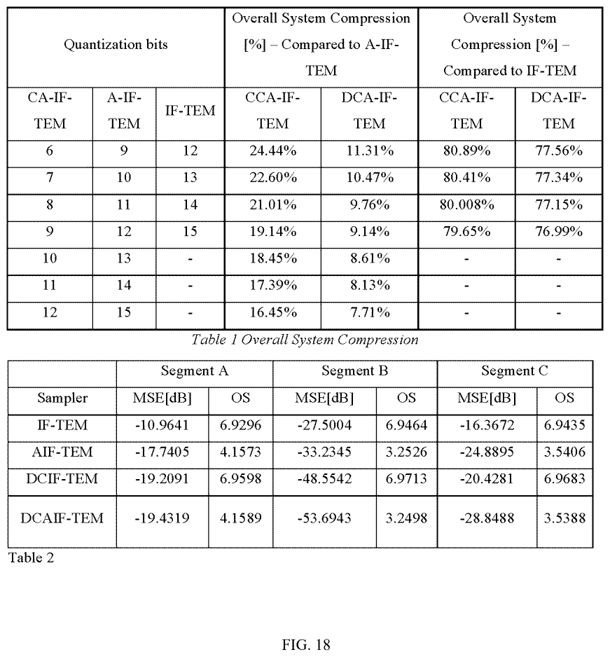

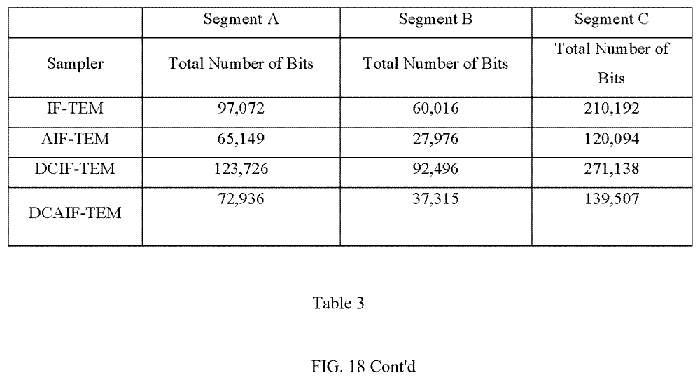

FIG. 16 illustrated the audio signals 195, 196 and 197 of table 2.

As we can see in table 2, the combined machine outperforms drastically the other machines in segments 2 and 3, proving that even with real-world signals the combined machine is a suitable choice. In segment 2, DCAIF-TEM achieves a MSE which is better by 5 [dB] compared to DCIF-TEM and better by 20 [dB] related to AIF-TEM. In segment 3, DCAIF-TEM outperforms DCIF-TEM and AIF-TEM by 4 [dB] and 8 [dB], respectively. In segment 1, in terms of MSE, the combined machine also obtains the best result even though the MSE difference with respect to DCIF-TEM is low. Nevertheless, the compressed machine requires a bigger oversampling, meaning more samples are needed.

A notable insight we can infer from table 2 is that the adaptive model achieves the smallest difference with respect to DCAIF-TEM in the segment where the changes in the signal are largest.

Finally, according to our results, DCAIF-TEM and AIF-TEM also obtained the smallest number of bits used, similarly to the results in the previous simulations.

Table 3 Audio signals illustrates bit comparison.

FIG. 12 illustrates an example of method 200 for sampling an analog signal.

Method 200 the method includes step 210 of preforming multiple sampling iterations to provide timing information that represents the analog signal at multiple points in time.

Each sampling iteration includes:
a. Adding (211) an adaptive bias to the analog signal to provide a biased signal. The adaptive bias is determined based on values of the analog signal during a set of previous sampling iterations.
b. Integrating (212) the biased signal by an integrator to provide an integration result.
c. Comparing (213) the integration result to a threshold.
d. Generating (214) a timestamp when the integration result exceeds the threshold.
e. Generating (215) a representation of a difference between the current timestamp to last generated timestamp.

According to an embodiment, each sampling iteration includes determining (216) the adaptive bias.

Step 216 may include step 216-1 of determining the adaptive bias based on an estimate of a maximal sampled value of the analog signal during the sampling iteration.

Step 216 may include step 216-2 of determining the adaptive bias based on variations in at least one of an amplitude and a frequency of the analog signal.

According to an embodiment, step 215 includes one or more steps of:
a. Step 215-1 of applying a fixed quantization.
b. Step 251-2 of applying a dynamic quantization that is responsive to an amplitude of the analog signal.
c. Step 215-3 of compressing the difference between the current timestamp to last generated timestamp.
d. Step 215-4 of dividing a variable that is indicative to a most significant portion and a least significant portion.

According to an embodiment, method 200 also includes step 217 of quantizing only the least significant portion and transmitting the most significant portion only when a value of the most significant portion differs from a last value of the most significant portion.

According to an embodiment, step 215-4 is based on an estimate of the maximal sampled value of the analog signal during the sampling iteration.

### CONCLUSIONS

In conclusion, we managed to improve the performance of IF-TEM machines, in terms of MSE, by combining existing models together. We demonstrated, according to our results, that a machine which contains both adaptive bias and analog compression not only has lower MSE, but also is more efficient in terms of total number of bits and memory used (given an appropriate parameters' selection).

Throughout this project, we have learned the theory and implementation behind the separated machines, particularly their architecture schemes, which made possible the achievement and optimization of a combined machine.

Important concepts that we need to consider in the implementation of our machine are a proper definition of a distortion metric (in our case, MSE) and obtaining a reasonable oversampling rate. We always tend to minimize the distortion metric, while ensuring the oversampling rate is not excessively high. An exaggerated number of samples translates into a bigger storage of bits.

An outstanding conclusion that accompanied us during the whole process is the importance of deciding an optimal configuration of parameters. A bad selection of parameters can make the whole difference in the performance, even though there were no changes to the algorithm itself.

There is a well-known statement among DSP experts that states that approximately 70% of the success of a DSP algorithm is attributed to a correct selection of parameters, while only the remaining 30% is influenced by the algorithm itself.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

The invention may also be implemented in a computer program for running on a computer system, at least including code portions for performing steps of a method according to the invention when run on a programmable apparatus, such as a computer system or enabling a programmable apparatus to perform functions of a device or system according to the invention. The computer program may cause the storage system to allocate disk drives to disk drive groups.

A computer program is a list of instructions such as a particular application program and/or an operating system. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system.

The computer program may be stored internally on a non-transitory computer readable medium. All or some of the computer program may be provided on computer readable media permanently, removably or remotely coupled to an information processing system. The computer readable media may include, for example and without limitation, any number of the following: magnetic storage media including disk and tape storage media; optical storage media such as compact disk media (e.g., CD-ROM, CD-R, etc.) and digital video disk storage media; nonvolatile memory storage media including semiconductor-based memory units such as flash memory, EEPROM, EPROM, ROM; ferromagnetic digital memories; MRAM; volatile storage media including registers, buffers or caches, main memory, RAM, etc.

A computer process typically includes an executing (running) program or portion of a program, current program values and state information, and the resources used by the operating system to manage the execution of the process. An operating system (OS) is the software that manages the sharing of the resources of a computer and provides programmers with an interface used to access those resources. An operating system processes system data and user input and responds by allocating and managing tasks and internal system resources as a service to users and programs of the system.

The computer system may for instance include at least one processing unit, associated memory and a number of input/output (I/O) devices. When executing the computer program, the computer system processes information according to the computer program and produces resultant output information via I/O devices.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein may be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method for sampling an analog signal, the method comprises:
preforming multiple sampling iterations to provide timing information that represents the analog signal at multiple points in time;
wherein each sampling iteration comprises:
adding an adaptive bias to the analog signal to provide a biased signal, wherein the adaptive bias is determined based on values of the analog signal during a set of previous sampling iterations;
integrating the biased signal by an integrator to provide an integration result;
comparing the integration result to a threshold;
generating a timestamp when the integration result exceeds the threshold;
generating a representation of a difference between the current timestamp to last generated timestamp.

2. The method according to claim 1, wherein each sampling iteration comprises determining the adaptive bias based on an estimate of a maximal sampled value of the analog signal during the sampling iteration.

3. The method according to claim 1, wherein each sampling iteration comprises determining the adaptive bias based on variations in at least one of an amplitude and a frequency of the analog signal.

4. The method according to claim 1, wherein the generating of the representation comprises applying a fixed quantization.

5. The method according to claim 1, wherein the generating of the representation comprises applying a dynamic quantization that is responsive to an amplitude of the analog signal.

6. The method according to claim 1, wherein the generating of the representation comprises compressing the difference between the current timestamp to last generated timestamp.

7. The method according to claim 1, wherein the generating of the representation comprises dividing a variable that is indicative to a most significant portion and a least significant portion

8. The method according to claim 7, further comprising quantizing only the least significant portion and transmitting the most significant portion only when a value of the most significant portion differs from a last value of the most significant portion.

9. The method according to claim 7, wherein the dividing of the variable is based on an estimate of the maximal sampled value of the analog signal during the sampling iteration.

10. A non-transitory computer readable medium that stores instructions executable by a hardware sampler for sampling an analog signal, by:
preforming multiple sampling iterations to provide timing information that represents the analog signal at multiple points in time;
wherein each sampling iteration comprises:
adding an adaptive bias to the analog signal to provide a biased signal, wherein the adaptive bias is determined based on values of the analog signal during a set of previous sampling iterations;
integrating the biased signal by an integrator to provide an integration result;
comparing the integration result to a threshold;
generating a timestamp when the integration result exceeds the threshold;
generating a representation of a difference between the current timestamp to last generated timestamp.

11. The non-transitory computer readable medium according to claim 10, wherein each sampling iteration comprises determining the adaptive bias based on an estimate of a maximal sampled value of the analog signal during the sampling iteration.

12. The non-transitory computer readable medium according to claim 10, wherein each sampling iteration comprises determining the adaptive bias based on variations in at least one of an amplitude and a frequency of the analog signal.

13. The non-transitory computer readable medium according to claim 10, wherein the generating of the representation comprises applying a fixed quantization.

14. The non-transitory computer readable medium according to claim 10, wherein the generating of the representation comprises applying a dynamic quantization that is responsive to an amplitude of the analog signal.

15. The non-transitory computer readable medium according to claim 10, wherein the generating of the representation comprises compressing the difference between the current timestamp to last generated timestamp.

16. The non-transitory computer readable medium according to claim 10, wherein the generating of the representation comprises dividing a variable that is indicative to a most significant portion and a least significant portion

17. The non-transitory computer readable medium according to claim 16, further storing instructions executable by the hardware sampler for quantizing only the least significant portion and transmitting the most significant portion only when a value of the most significant portion differs from a last value of the most significant portion.

18. The non-transitory computer readable medium according to claim 16, wherein the dividing of the variable is based on an estimate of the maximal sampled value of the analog signal during the sampling iteration.

19. A hardware sample for sampling an analog signal, the hardware sampler comprises:
one or more processing circuits that are configured to execute instructions that cause the one or more processing circuits to preform multiple sampling iterations to provide timing information that represents the analog signal at multiple points in time;
wherein each sampling iteration comprises:
adding an adaptive bias to the analog signal to provide a biased signal,
wherein the adaptive bias is determined based on values of the analog signal during a set of previous sampling iterations;
integrating the biased signal by an integrator to provide an integration result;
comparing the integration result to a threshold;
generating a timestamp when the integration result exceeds the threshold; and
generating a representation of a difference between the current timestamp to last generated timestamp.
